(19) United States
(12) Patent Application Publication
(10) Pub. No.: US 2003/0058688 A1
(43) Pub. Date: Mar. 27, 2003

(54) Integrated circuit for concurent flash memory

(76) Inventor: Tam Nguyen, San Jose, CA (US)

Correspondence Address: David L. Alberti, GRAY CARY WARE & FREIDENRICH, Attn: Patent Group, 1755 Embarcadero Road, Palo Alto, CA, 94303-3340, US

(21) Appl. No.: 09/966,554

(22) Filed: Sep. 26, 2001

(51) Int. Cl. G11C 11/34

(52) U.S. Cl. 365/185.11

(57) ABSTRACT

An integrated circuit 10 for concurrent flash memory. The circuit 10 includes a plurality of memory arrays 12, each including local X-decoding circuits 36 and Y-decoding circuits 38, 40, which are effective to select desired locations within memory arrays 12 for reading and writing. Global read and write bitlines 14, 16 respectively traverse each of said arrays 12, and are selectively and communicatively coupled to each of arrays 12. Pre-decoders 22, 24 provide pre-decoded address signals to read/write address multiplexers 42, which utilize the signals to select specific memory arrays 12 for reading and writing. Read/write data multiplexers 44 couple local bitlines within the selected memory arrays 12 to the read and write global bitlines 14, 16, thereby allowing data to be respectively accessed from and written to the selected locations within memory arrays 12.

### FIELD OF THE INVENTION

The present invention relates to an integrated circuit for concurrent flash memory and more particularly, to an integrated circuit for concurrent flash memory having a simplified architecture which includes a pair of global bitlines for performing concurrent read and write operations.

### BACKGROUND OF THE INVENTION

Semiconductor memory devices typically employ integrated circuits, such as flash memory type circuits, having multiple memory cells to store and access electronic data. One type of integrated circuit, commonly referred to as a concurrent flash memory circuit, utilizes multiple arrays of memory cells to allow read and write (e.g., program/erase) operations to be performed simultaneously. Particularly, in this type of circuit, a first bank of memory cells comprising one or more arrays can be read while a second bank of memory cells comprising different arrays is concomitantly programmed or erased.

While conventional concurrent flash type integrated circuits are effective to simultaneously perform read and write operations, they suffer from some drawbacks. By way of example and without limitation, in order to perform simultaneous reading and writing, these prior concurrent flash type circuits typically employ several disparate banks of memory cells that are selectively interconnected by a relatively complex network of buses and components. This relatively complex architecture undesirably increases the cost and difficulty of producing the integrated circuits, while undesirably affecting the performance of the circuits.

There is therefore a need for a new and improved integrated circuit for concurrent flash memory having a simplified architecture which utilizes a global read bitline and a global write bitline to perform simultaneous memory operations.

### SUMMARY OF THE INVENTION

A first non-limiting advantage of the invention is that it provides an integrated circuit for concurrent flash memory having a simplified architecture.

A second non-limiting advantage of the invention is that it provides an integrated circuit for concurrent flash memory having a simplified architecture including a global read bitline and a global write bitline for performing simultaneous memory operations.

According to a first aspect of the present invention, an integrated circuit for concurrent flash memory is provided. The circuit includes a plurality of memory cell arrays; a global write bitline which traverses each of the plurality of memory cell arrays; a global read bitline which traverses each of the plurality of memory cell arrays; and an array selection circuit which is coupled to the plurality of memory cell arrays and to the global write and read bitlines. The array selection circuit is adapted to select a first memory cell array for writing and to connect the global write bitline to the first memory cell array, thereby allowing a write operation to be performed on the first memory cell array, and to further select a second memory cell array for reading and to connect the global read bitline to the second memory cell array, thereby allowing a read operation to be performed on the second memory cell array while said write operation is simultaneously performed on said first memory cell array.

According to a second aspect of the present invention, an integrated circuit for concurrent flash memory is provided. The integrated circuit includes a plurality of memory cell arrays, each including local decoding circuits for selecting locations within the memory cell arrays for read and write operations; a global write bitline which traverses each of the plurality of memory cell arrays; a global read bitline which traverses each of the plurality of memory cell arrays; a read address pre-decoder which pre-decodes a read address; and a write address pre-decoder which pre-decodes a write address. A plurality of address multiplexers are coupled to the read and write address pre-decoders and to the plurality of memory cell arrays. The plurality of address multiplexers are adapted to receive the pre-decoded read and write addresses, and to select a first memory cell array to perform a write operation, based upon the pre-decoded write address, and a second memory cell array to perform a read operation, based upon the pre-decoded read address. A plurality of data multiplexers are coupled to the plurality of address multiplexers and are adapted to connect the first memory array to the global write bitline, while the second memory array is connected to the global read bitline, thereby allowing the first memory array to be programmed or erased while the second memory array is simultaneously read.

According to a third aspect of the present invention, a method is provided for performing concurrent memory operations within a memory device including a plurality of memory cell arrays, each having a plurality of local bitlines. The method includes the steps of: providing a global read bitline which traverses each of the plurality of memory cell arrays; providing a global write bitline which traverses each of the plurality of memory cell arrays; selecting a first of the memory cell arrays to perform a read operation; connecting at least one first local bitline from the first of the memory cell arrays to the global read bitline; selecting a second of the memory cell arrays to perform a write function; connecting at least one second local bitline from the second of the memory cell arrays to the global write bitline; and reading data at a first location within the first of the memory cell arrays by use of the global read bitline and the at least one first local bitline, while simultaneously writing data to a second location within the second of the memory cell arrays by use of the global write bitline and the at least one second local bitline.

These and other features, advantages, and objects of the invention will become apparent by reference to the following specification and by reference to the following drawings.

### BRIEF DESCRIPTION OF THE DRAWINGS

FIG. 1 is a block diagram illustrating an integrated circuit for concurrent flash memory in accordance with the preferred embodiment of the invention.

FIG. 2 is a schematic circuit diagram illustrating a portion of the circuit shown in FIG. 1.

### DETAILED DESCRIPTION OF THE PREFERRED EMBODIMENT OF THE INVENTION

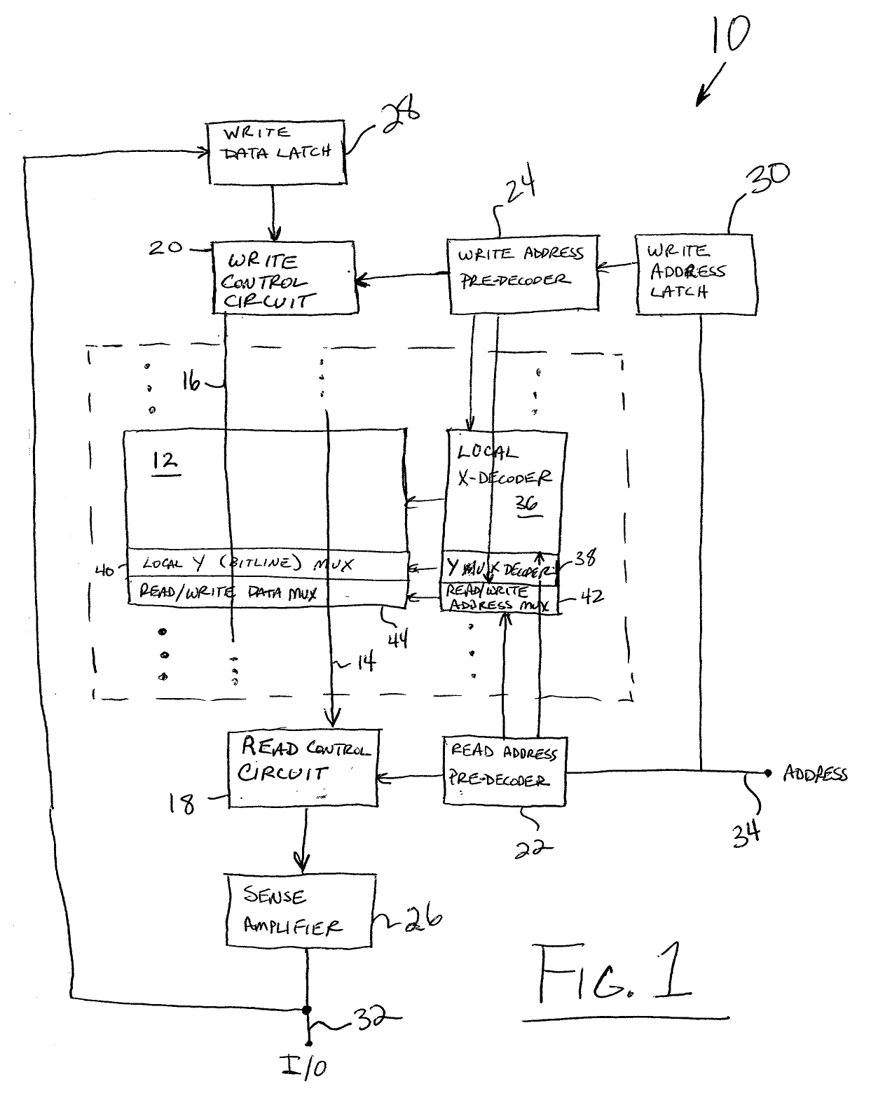

Referring now to FIG. 1, there is shown an integrated circuit 10 for concurrent flash memory that is made in accordance with a preferred embodiment of the present invention and which is adapted for use within a conventional semiconductor integrated circuit device. It should be appreciated by one of ordinary skill in the art that a semiconductor integrated circuit device may employ several substantially identical circuits 10 in a cooperative manner to perform various conventional memory functions.

Circuit 10 includes several arrays 12 (although only one is shown in the drawing), each including a plurality of non-volatile memory cells (not shown) which are connected together in a two-dimensional configuration of rows and columns. Memory cells within the same column each share a common local bitline. It should be appreciated that the term “array,” as used herein, may refer to any group, block, sector, array or sub-array comprising one or more rows of memory cells that may be selected for read and write (e.g., program/erase) operations. In the preferred embodiment, the memory cells are flash type memory cells, which may be stacked-gate, split-gate or any other type of flash memory cells.

Each array 12 is communicatively coupled to a local X-decoder circuit 36, a local Y-multiplexer decoder circuit 38, a local Y-bitline multiplexer 40, a local read/write address multiplexer 42, and a local read/write data multiplexer 44. Each local X-decoder circuit 36 includes a plurality of conventional X-decoders and multiplexers, which are effective to select certain rows (e.g., word lines), blocks or sectors of the local memory array 12, based upon signals received from address bus 34 through pre-decoders 22, 24. Each local Y-multiplexer decoder circuit 38 includes a plurality of conventional Y-decoders, and each local bitline multiplexer circuit 40 includes a plurality of conventional multiplexers. Circuits 38, 40 cooperate to select certain columns (e.g., local bitlines) of the local memory array 12, based upon signals received from address bus 34, through pre-decoders 22, 24. In this manner, circuits 36, 38 and 40 cooperate to select desired locations within memory array 12 for performing read or write operations.

Multiplexer circuits 42, 44 each include a plurality of conventional multiplexers and cooperatively form an array selection circuit. That is, circuits 42 and 44 respectively select and activate certain memory arrays 12 for read and write operations based upon the pre-decoded address signals received by pre-decoders 22, 24, in a manner described more fully and completely below.

Circuit 10 further includes a pair of global bitlines 14, 16 which respectively traverse each of arrays 12, and which are selectively and communicatively coupled to each of arrays 12 by the associated read/write data multiplexer. In the preferred embodiment, global bitline 14 is designated for read operations and is communicatively coupled to a read control circuit 18, which controls the timing and execution of the read operations performed by circuit 10. Read control circuit 18 is communicatively coupled to read address pre-decoder circuit 22 and to a sense amplifier circuit 26. In the preferred embodiment, global bitline 16 is designated for write operations (e.g., programming/erasing) and is communicatively coupled to write control circuit 20, which controls the timing and execution of the write operations performed by circuit 10. Write control circuit 20 is further communicatively coupled to a write address pre-decoder circuit 24 and a write data latch 28. Write data latch 28 includes one or more conventional latches which receive and store data from input/output or data bus 32. Write address pre-decoder circuit 24 is further communicatively coupled to a write address latch 30. Write address latch 30 includes one or more conventional latches which receive and store data (which are in the nature of address locations) from address bus 34. The foregoing elements of circuit 10 each include and/or are formed from conventional circuit components, the function of which will be discussed more fully and completely below.

It should be appreciated that the circuit 10 illustrated in FIG. 1 has been simplified for illustrative purposes and that a memory device employing the present invention may further include additional and/or different circuit elements which assist in the reading and writing of data to and from arrays 12 such as additional buses, sense amplifiers, multiplexers, buffers, counters, shift registers, logic circuits and other circuit components necessary and/or desirable to read, program and erase data.

In operation, circuit 10 may perform read and write operations concurrently. Circuit 10 performs a read operation as follows. Address bus 34 communicates a “read” address (i.e., an address that has been selected for reading) to read address pre-decoder 22. Pre-decoder 22 partially decodes the address in a conventional manner. Particularly, pre-decoder 22 decodes a first portion or bit sequence of the address which defines the specific array 12 in which the read address resides. Pre-decoder 22 then communicates the pre-decoded address to read control circuit 18 and to read/write address multiplexers 42.

Read/write address multiplexers 42 operate to select only the specific array 12 in which the read address is located, based upon the value of the pre-decoded address signal (i.e., based upon the value of the decoded portion of the address signal). Pre-decoder 22 communicates the remainder or “undecoded” portion of the address signal to the local X-decoder 36 and local Y-multiplexer decoder 38 of the selected array 12. The local X-decoder 36 and local Y-multiplexer decoder 38 cooperatively complete the decoding of the address signal in a conventional manner, effective to select the specific location(s) (i.e., the specific row(s) and column(s)) that have been designated for reading.

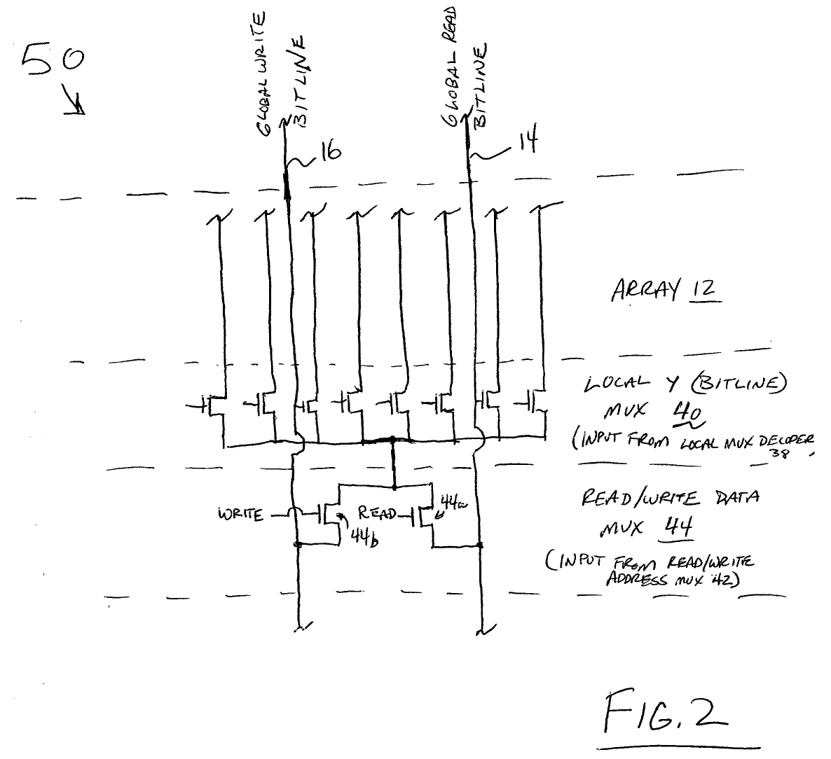

Read/write address multiplexer 42 provides a control signal to read/write data multiplexer 44, which utilizes the control signal to communicate the data within the selected location to the global read bitline 14. For a better understanding of the operation of data multiplexer 44, reference is now made to circuit diagram 50 of FIG. 2. As shown in diagram 50, data multiplexer 44 is communicatively coupled to both the global read bitline 14 and the global write bitline 16, and receives an input or control signal from read/write address multiplexer 42. In the preferred embodiment, the “default” state of data multiplexer 44 corresponds to a read operation. Particularly, transistor 44a is “turned on” or activated in the default state, effective to connect global read bitline 14 to array 12, thereby allowing data from selected portions of array 12 to be communicated to global read bitline 14.

Read control circuit 18 receives the accessed or read data from bitline 14, which is connected to the local bitline of the selected array 12, and communicates the data from the local bitline of the selected array 12, which in turn is connected to the selected memory cell, as determined by the address decoded by the local X and local Y decoders 36, 38, respectively, to sense amplifier circuit 26 in a controlled manner. Sense amplifier circuit 26 amplifies the data signal to a desirable level before the data is outputted or transmitted over data bus 32.

While circuit 10 is reading data, a write operation may be simultaneously performed as follows. Address bus 34 provides multiplexed address signals for both read and write operations, although the read and write addresses may be supplied on two separate address buses. Address bus 34 communicates a “write” address (i.e., an address that has been selected for writing or programming/erasing) to write address latch 30. Latch 30 holds the address until a write operation can be performed (e.g., until any ongoing writing operations are completed). The write address is then communicated to write address pre-decoder 24. Pre-decoder 24 partially decodes the address in a conventional manner. Particularly, pre-decoder 24 decodes a first portion or bit sequence of the address which defines the specific array 12 in which the write address resides. Pre-decoder 24 then communicates the pre-decoded address to write control circuit 20 and to read/write address multiplexers 42.

Read/write address multiplexers 42 operate to activate or select only the array 12 that is desired to be programmed or erased, based upon the value of the pre-decoded signal (e.g., based upon the value of the decoded portion of the signal). Pre-decoder 24 communicates the remainder or undecoded portion of the address signal to the local X-decoder 36 and Y-multiplexer decoder 38 of the selected array 12. Decoders 36, 38 cooperatively complete decoding of the address signal in a conventional manner, effective to select the desired location(s) (i.e., the row(s) and column(s) of array 12) that have been selected for writing.

The selected location is then accessed through the global write bitline 16 by use of data multiplexer 44. Particularly, when a write operation is desired, the transistor 44a will be “turned off” or deactivated, and the transistor 44b will be activated, thereby allowing data from global write bitline 16 to be written to the selected location. In order to respectively deactivate and activate transistors 44a and 44b, read/write multiplexer 42 provides an input or control signal to multiplexer 44 when a write address is selected. In the preferred embodiment, multiplexer 42 detects the selection of a write address by the presence of a conventional write enable bit which is communicated to multiplexer 42 by write address pre-decoder 24. Upon receipt of a write enable bit, multiplexer 42 communicates a corresponding control signal to multiplexer 44, effective to respectively deactivate and activate transistors 44a and 44b. Once transistor 44b is “turned on” or activated, global write bitline 16 will be communicatively coupled or connected to the selected location(s) of array 12. Write control circuit 20 may then program the data contained within write data latch 28 into the selected locations of array 12. Alternatively, circuit 20 may cause the data contained within the selected locations of array 12 to be erased.

Because write operations may take a long period of time to perform relative to read operations, it should be appreciated that many different read operations may be executed while a write operation is being performed. Particularly, while the write address is held in latch 30, circuit 10 can perform read operations in any of the arrays 12 that are not concomitantly being programmed or erased.

It should further be appreciated that the present invention provides a simplified architecture which requires fewer buses, decoders and other circuit components to perform concurrent read and write operations. The present invention achieves this superior architecture and performance through the use of global read and write bitlines 14, 16, which respectively traverse each of memory arrays 12 and which are selectively connected to local bitlines within the arrays 12. This superior architecture employs a single “read” circuit (e.g., control circuit 18, pre-decoder 22 and sense amplifier circuit 26) and a single “write” circuit (e.g., latches 28, 30, control circuit 20 and pre-decoder 24) to perform simultaneous read and write operations.

It should be understood that the inventions described herein are provided by way of example only and that numerous changes, alterations, modifications, and substitutions may be made without departing from the spirit and scope of the inventions as delineated within the following claims.

What is claimed is:

1) An integrated circuit for concurrent flash memory comprising:
a plurality of memory cell arrays;
a global write bitline which traverses each of said plurality of memory cell arrays;
a global read bitline which traverses each of said plurality of memory cell arrays; and
an array selection circuit which is coupled to said plurality of memory cell arrays and which is adapted to select a first memory cell array for writing and to connect said global write bitline to said first memory cell array, thereby allowing a write operation to be performed on said first memory cell array, and to further select a second memory cell array for reading and to connect said global read bitline to said second memory cell array, thereby allowing a read operation to be performed on said second memory cell array while said write operation is simultaneously performed on said first memory cell array.

2) The integrated circuit of claim 1 wherein each of said plurality of memory cell arrays includes a plurality of local bitlines, and further comprising:
a plurality of data multiplexer circuits, each of which is communicatively coupled to a unique plurality of local bitlines, and is effective to selectively connect said global read bitline or said global write bitline to said associated plurality of local bitlines, thereby allowing said read or write operations to be performed.

3) The integrated circuit of claim 2 further comprising:
a plurality of local decoding circuits each of which is coupled to a unique one of said plurality of memory cell arrays, and is adapted to select specific locations within said associated memory cell array for reading and writing.

4) The integrated circuit of claim 2 wherein said array selection circuit comprises a plurality of address multiplexers which are adapted to select said first and second memory cell arrays.

5) The integrated circuit of claim 2 further comprising:
a write address pre-decoder which is coupled to said array selection circuit and which is adapted to pre-decode a write address and to communicate said pre-decoded write address to said array selection circuit; and
a read address pre-decoder which is coupled to said array selection circuit and which is adapted to pre-decode a read address and to communicate said pre-decoded read address to said array selection circuit.

6) The integrated circuit of claim 2 further comprising:
a write control circuit which is coupled to said global write bitline and which selectively provides data to said global write bitline for writing into said first memory cell array; and
a read control circuit which is coupled to said global read bitline and which receives data from said second memory array through said global read bitline and selectively outputs said received data.

7) The integrated circuit of claim 2 wherein said memory cells comprise flash type memory cells.

8) An integrated circuit for concurrent flash memory comprising:
a plurality of memory cell arrays, each including local decoding circuits for selecting locations within said memory cell arrays for read and write operations;
a global write bitline which traverses each of said plurality of memory cell arrays;
a global read bitline which traverses each of said plurality of memory cell arrays;
a read address pre-decoder which pre-decodes a read address;
a write address pre-decoder which pre-decodes a write address;
a plurality of address multiplexers which are coupled to said read and write address pre-decoders and to said plurality of memory cell arrays, said plurality of address multiplexers being adapted to receive said pre-decoded read and write addresses, and to select a first memory cell array to perform a write operation, based upon said pre-decoded write address, and a second memory cell array to perform a read operation, based upon said pre-decoded read address; and
a plurality of data multiplexers which are coupled to said plurality of address multiplexers and which are adapted to connect said first memory cell array to said global write bitline, while said second memory array is connected to said global read bitline, thereby allowing said first memory array to be programmed or erased while said second memory array is simultaneously read.

9) The integrated circuit of claim 8 wherein each of said plurality of memory cell arrays includes a plurality of local bitlines, which are coupled to a unique one of said data multiplexers, said data multiplexers being effective to selectively connect said global read bitline or said global write bitline to said associated plurality of local bitlines, thereby allowing said read or write operations to be performed.

10) The integrated circuit of claim 9 further comprising:
a read control circuit which is coupled to said read address pre-decoder and to said global read bitline and which is adapted to control said read operations.

11) The integrated circuit of claim 9 further comprising:
a write control circuit which is coupled to said write address pre-decoder and to said global write bitline and which is adapted to control said write operations.

12) The integrated circuit of claim 11 further comprising:
a write data latch which is coupled to said write control circuit and which is adapted to hold data for said write operations.

13) The integrated circuit of claim 12 further comprising:
a write address latch which is coupled to said write address pre-decoder and which is adapted to hold at least one write address.

14) A method of performing concurrent memory operations within a memory device including a plurality of memory cell arrays, each having a plurality of local bitlines, said method comprising the steps of:
providing a global read bitline which traverses each of said plurality of memory cell arrays;
providing a global write bitline which traverses each of said plurality of memory cell arrays;
selecting a first of said memory cell arrays to perform a read operation;
connecting at least one first local bitline from said first of said memory cell arrays to said global read bitline;
selecting a second of said memory cell arrays to perform a write function;
connecting at least one second local bitline from said second of said memory cell arrays to said global write bitline; and
reading data at a first location within said first of said memory cell arrays by use of said global read bitline and said at least one first local bitline, while simultaneously writing data to a second location within said second of said memory cell arrays by use of said global write bitline and said at least one second local bitline.

15) The method of claim 14 wherein said first of said memory cell arrays is selected by use of a first pre-decoder and a plurality of address multiplexers.

16) The method of claim 15 wherein said second of said memory cell arrays is selected by use of a second pre-decoder and said plurality of address multiplexers.

17) The method of claim 14 wherein said first location is determined by use of a first plurality of local decoders, and said second location is determined by use of a second plurality of local decoders.

18) The method of claim 13 wherein said at least one first local bitline and said at least one second local bitline are respectively connected to said global read and write bitlines by use of first and second data multiplexer circuits.

19) The method of claim 14 further comprising the step of:
amplifying said read data by use of a sense amplifier circuit.
